(19) United States
(12) Patent Application Publication
(10) Pub. No.: US 2024/0133809 A1
(43) Pub. Date: Apr. 25, 2024

(54) OPTICAL STABILIZATION TECHNIQUES INCORPORATING PIXEL CURRENT MEASUREMENTS

(71) Applicant: Quantum-Si Incorporated, Branford, CT (US)

(72) Inventors: Todd Rearick, Cheshire, CT (US); Shannon Stewman, Guilford, CT (US)

(21) Appl. No.: 18/490,713

(22) Filed: Oct. 18, 2023

Related U.S. Application Data
(60) Provisional application No. 63/418,004, filed on Oct. 20, 2022.

(51) Int. Cl. G01N 21/64; H01L 27/146

(52) U.S. Cl. CPC G01N 21/64; H01L 27/14625; H01L 27/14643

(57) ABSTRACT

Described herein are techniques for determining an illumination position on an integrated photodetector, as may be used within a fluorescence detection system. In some embodiments, such techniques may include determining an illumination position on an integrated photodetector based, at least in part, on a measurement of an amount of current output from a pixel of the integrated photodetector, the amount of current corresponding to an amount of excitation light (e.g., used for exciting fluorescence in a sample) that is received at the pixel. In some embodiments, such techniques may include measuring an amount of current output from one or more drain regions of one or more pixels of an integrated photodetector (e.g., regions used to draw away charge carriers corresponding to excitation light so as to not pollute collected charge carriers that correspond to fluorescence light to be detected).

### RELATED APPLICATIONS

This application claims the benefit under 35 U.S.C. § 119(e) of U.S. Provisional Application Ser. No. 63/418,004, filed Oct. 20, 2022, under Attorney Docket No.: R0708.70166US00, and entitled, “OPTICAL STABILIZATION TECHNIQUES INCORPORATING PIXEL CURRENT MEASUREMENTS,” which is hereby incorporated herein by reference in its entirety.

### FIELD OF THE DISCLOSURE

The present disclosure relates to integrated devices and related instruments that can perform massively-parallel analyses of samples by providing short optical pulses to tens of thousands of sample wells or more simultaneously and receiving fluorescent signals from the sample wells or sample analyses. The instruments may be useful for point-of-care genetic sequencing and for personalized medicine.

### BACKGROUND

Photodetectors are used to detect light in a variety of applications. Integrated photodetectors have been developed that produce an electrical signal indicative of the intensity of incident light. Integrated photodetectors for imaging applications include an array of pixels to detect the intensity of light received from across a scene. Examples of integrated photodetectors include charge coupled devices (CCDs) and Complementary Metal Oxide Semiconductor (CMOS) image sensors.

Instruments that are capable of massively-parallel analyses of biological or chemical samples are typically limited to laboratory settings because of several factors that can include their large size, lack of portability, requirement of a skilled technician to operate the instrument, power need, need for a controlled operating environment, and cost. When a sample is to be analyzed using such equipment, a common paradigm is to extract a sample at a point of care or in the field, send the sample to the lab and wait for results of the analysis. The wait time for results can range from hours to days.

### SUMMARY OF THE DISCLOSURE

Some aspects of the present disclosure relate to a method comprising determining an illumination position on an integrated photodetector based, at least in part, on a measurement of an amount of current output from a pixel of the integrated photodetector, the amount of current corresponding to an amount of excitation light received at the pixel.

Some aspects of the present disclosure relate to a method comprising measuring an amount of current output from a drain region of a pixel of an integrated photodetector.

Some aspects of the present disclosure relate to a method comprising determining an illumination position on an integrated photodetector based, at least in part, on a measurement of current output from a drain region of a pixel of the integrated photodetector.

Some aspects of the present disclosure relate to method comprising measuring an amount of current output from a pixel of an integrated photodetector, the amount of current corresponding to an amount of excitation light received at the pixel.

The foregoing summary is not intended to be limiting. In addition, various embodiments may include any aspects of the disclosure either alone or in combination.

### BRIEF DESCRIPTION OF DRAWINGS

FIG. 1 is a block diagram of an example fluorescence detection system, according to some embodiments.

FIG. 2 is a perspective view of an example integrated device that may be included in the system of FIG. 1, according to some embodiments.

FIG. 3 is an annotated top view of the integrated circuit of the integrated device of FIG. 2, according to some embodiments.

FIG. 4A is a top view of optical components of an integrated device that may be configured to deliver excitation light to pixels of the integrated device, according to some embodiments.

FIG. 4B is an enlarged top view of the grating coupler of the integrated device of FIG. 4A, according to some embodiments.

FIG. 5 is a side view of a cross-section of a dimension a pixel array of the integrated circuit of FIG. 2, according to some embodiments.

FIG. 6 is a side view of the cross-section of the dimension of the pixel array shown in FIG. 5 further illuminated with excitation light that excites a sample in the reaction chambers, according to some embodiments.

FIG. 7 is a side view of a cross-section of a pixel that may be included in the integrated device of FIG. 2, according to some embodiments.

FIG. 8A is a top view of a photodetector that may be included in the integrated device of FIG. 2 during an excitation light pulse, according to some embodiments.

FIG. 8B is a graph of voltage over time at two transfer gates of the photodetector of FIG. 8A superimposed with timing of a pulse of excitation light illuminating a sample, according to some embodiments.

FIG. 8C is a top view of the photodetector of FIG. 8A during a fluorescent emission, according to some embodiments.

FIG. 8D is a graph of voltage over time at the two transfer gates of the photodetector of FIG. 8A superimposed with the timing of the pulse of excitation light and further superimposed with the timing of a fluorescent emission collected in the photodetector, according to some embodiments.

FIG. 9 is a top view of an example configuration of the integrated circuit of FIG. 3 superimposed with lines representing optical components that may be configured to provide excitation light to groups of pixels of the integrated circuit, according to some embodiments.

FIG. 10 is a circuit diagram of an example measurement circuit that may be included in the integrated circuit of FIG. 3, according to some embodiments.

FIG. 11 is a top view of an alternative example configuration of the integrated circuit of FIG. 3 superimposed with lines representing optical components that may be configured to provide excitation light to groups of pixels of the integrated circuit, according to some embodiments.

FIG. 12 is a graph of current amplitude vs. normalized illumination position for currents that may be output from respective pixels or groups of pixels of an integrated circuit and measured using respective measurement circuits over an illumination sweep in a first direction, according to some embodiments.

FIG. 13 is a graph of current amplitude vs. normalized illumination position for a difference between the measured currents of FIG. 12, according to some embodiments.

FIG. 14A is a graph of current amplitude vs. normalized illumination position for measured currents that may be output from pixels or groups of pixels of an integrated circuit using respective measurement circuits over an illumination sweep in a second direction, according to some embodiments.

FIG. 14B is a graph of current amplitude vs. normalized illumination position for a difference between the measured currents of FIG. 14B, according to some embodiments.

FIG. 15 is a graph of current amplitude vs. motor position for currents measured from measurement circuits of an integrated circuit in response to a motor-driven illumination sweep in a first direction, according to some embodiments.

FIG. 16 is a graph of current amplitude vs. motor position for a difference between the measured currents of FIG. 15, according to some embodiments.

FIG. 17 is a graph of motor drift distance vs. normalized current amplitude for the difference between the measured currents and motor positions of FIG. 16, according to some embodiments.

FIG. 18 is a graph of current amplitude vs. time for measured currents from respective measurement circuits of an integrated circuit, according to some embodiments.

The features and advantages of the present disclosure will become more apparent from the detailed description set forth below when taken in conjunction with the drawings. When describing embodiments in reference to the drawings, directional references (“above,” “below,” “top,” “bottom,” “left,” “right,” “horizontal,” “vertical,” etc.) may be used. Such references are intended merely as an aid to the reader viewing the drawings in a normal orientation. These directional references are not intended to describe a preferred or only orientation of features of an embodied device. A device may be embodied using other orientations.

### DETAILED DESCRIPTION

### I. Introduction

Aspects of the present disclosure provide techniques for determining an illumination position on an integrated photodetector, as may be used within a fluorescence detection system. In some embodiments, such techniques may include determining an illumination position on an integrated photodetector based, at least in part, on a measurement of an amount of current output from a pixel of the integrated photodetector, the amount of current corresponding to an amount of excitation light (e.g., used for exciting fluorescence in a sample) that is received at the pixel. In some embodiments, such techniques may include measuring an amount of current output from one or more drain regions of one or more pixels of an integrated photodetector (e.g., regions used to draw away charge carriers corresponding to excitation light so as to not pollute collected charge carriers that correspond to fluorescence light to be detected). Embodiments of the present disclosure may be useful in a fluorescence detection system for substantially aligning an excitation light source with an integrated photodetector.

In some embodiments, a fluorescence detection system may include an excitation light source and an integrated photodetector. In some embodiments, an integrated photodetector may include reaction chambers (e.g., sample wells) configured to support a biological sample for excitation by the excitation light source. In some embodiments, the integrated photodetector may further include photodetectors positioned to receive fluorescent light from the sample when the sample is excited using the excitation light source. In some embodiments, the photodetectors may be configured to convert the received light into charge carriers and collect charge carriers that correspond to the received fluorescent light to be digitized and analyzed using a processor, allowing for computational analysis of the sample. In some embodiments, the photodetectors may be further configured to discriminate the fluorescent light from among excitation light that reaches the photodetectors. In some embodiments. the photodetectors may be configured to transfer, to a drain region of each photodetector, charge carriers generated in response to receiving the excitation light, thereby preventing the charge carriers from polluting collected charge carriers that correspond to the received fluorescent light.

In some embodiments, it is desirable to substantially align an excitation light source with one or more optical components of an integrated photodetector that spread the excitation light among a large array of reaction chambers. For example, the excitation light source may be configured to focus a beam of excitation light to be aligned with a grating coupler of the integrated photodetector. In some embodiments, misalignment may result from the initial assembly process, movement of the system, and/or ordinary ambient temperature variations in the operating environment (e.g., Heating, Ventilation, and Air Conditioning (HVAC) equipment cycling in an indoor operating environment). Consequently, in some embodiments, when the beam of light is misaligned with respect to the optical component(s), excitation light may be distributed unequally throughout the reaction chambers of the integrated photodetector, resulting in nonuniform and potentially unusable fluorescence measurements. The inventors have also recognized that it is challenging, in some embodiments, to substantially align an excitation light source with an integrated photodetector due to the precision that may be needed for proper alignment. For instance, while charge generated and collected in the photodetectors in response to the fluorescence light could be used, in some embodiments, to determine whether the reaction chambers have been nonuniformly illuminated, in other embodiments, it may be difficult or impossible to discriminate artifacts of nonuniform illumination from nonuniformity in the sample itself.

To overcome these problems, the inventors developed techniques for using measurements of current output from an integrated photodetector to determine an illumination position on an integrated photodetector, which may be useful to substantially align the integrated photodetector with an excitation light source. In some embodiments, such techniques include measuring an amount of current output from one or more drain regions of one or more pixels of an integrated photodetector. For example, the current output from the drain region(s) of the pixel(s) may correspond to an amount of excitation light that reached the pixel(s). By measuring the amount of current output from the drain region(s) of the pixel(s) of the integrated photodetector, a degree of alignment with respect to the excitation light source may be determined and potentially controlled (e.g., using the current measurements as feedback). It should be appreciated that measured current may be positive, such as indicating electrons flowing to the drain region(s) of the pixel(s), and/or negative, such as indicating electrons flowing from the drain region of the pixel(s) (e.g., or holes flowing to the drain region(s)).

In some embodiments, first and second charge carriers may be generated in the pixel(s), with some of the charge carriers collected in one or more charge storage regions of the pixel(s) and other charge carriers transferred to the drain region(s). For example, the current output from the drain region(s) of the pixel(s) may correspond to the amount of charge carriers transferred to the drain region(s). For instance, the charge carriers collected in the charge storage region(s) may correspond to fluorescent light from a sample supported by the integrated photodetector and the charge carriers transferred to the drain region(s) may correspond to excitation light that reaches the pixel(s).

In some embodiments, such techniques may include measuring a first amount of current output from at least one first drain region of at least one first pixel and measuring a second amount of current output from at least one second drain region at least one second pixel. For example, the first pixel(s) and the second pixel(s) may be configured to receive excitation light from optical components (e.g., portions of a grating coupler) of the integrated photodetector that are offset in a first direction. In this example, measuring amounts of current discarded by the pixels may be used to determine (and/or control) a degree of alignment in the first direction in which the optical components, providing excitation light to the pixels, are offset from one another. In some embodiments, a third amount of current output from at least one third drain region of at least one third pixel may be measured, allowing the third amount of current to be used in combination with the first and second amounts of current to determine (and/or control) a degree of alignment in at least two substantially perpendicular directions.

In some embodiments, such techniques may include determining an illumination position on an integrated photodetector based, at least in part, on a measurement of current output from one or more drain regions of one or more pixels of the integrated photodetector. For example, a processor (e.g., coupled to and/or onboard the integrated photodetector) may be configured to receive one or more such measurements from the integrated photodetector for use in determining the illumination position. In some embodiments, the processor(s) may be configured to adjust positioning (e.g., using a control signal input to a motorized assembly) of an excitation light source with respect to the integrated photodetector to illuminate another illumination position, offset from the illumination position, in response to determining the illumination position (e.g., in response to determining that the illumination position is substantially misaligned). By controlling the excitation light source using one or more measurements of current output from one or more pixels of the integrated photodetector, the excitation light source and integrated photodetector may be substantially aligned with one another.

In some embodiments, such techniques may include substantially aligning an excitation light source with an optical component (e.g., grating coupler) of an integrated photodetector in a first direction (and/or a second direction substantially perpendicular to the first direction) by moving the integrated photodetector and/or the excitation light source (e.g., changing the relative positioning of the integrated photodetector and excitation light source) to illuminate an illumination position on the integrated photodetector determined based, at least in part, on at least one measurement of current output from at least one pixel of the integrated photodetector. It should be appreciated that positions of either or each of the excitation light source and the integrated photodetector may be adjusted for substantial alignment, for instance by changing their relative positioning and/or by steering the excitation light source, as embodiments described herein are not so limited.

In some embodiments, such techniques may include measuring an amount of current output from at least one pixel of an integrated photodetector, the amount of current corresponding to an amount of excitation light received at the pixel(s).

It should be appreciated that techniques described herein may be used alone or in any combination, as embodiments described herein are not so limited.

### II. Integrated Device Overview

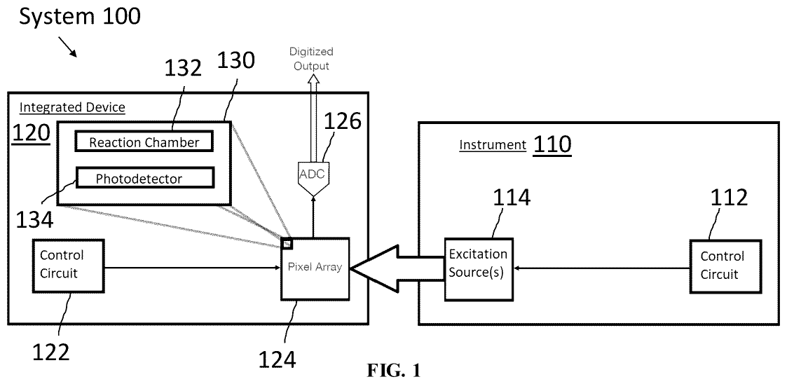

FIG. 1 is a block diagram of an example fluorescence detection system 100, according to some embodiments.

As shown in FIG. 1, the system 100 includes an instrument 110 and an integrated device 120. In some embodiments, the instrument 110 may include an excitation source 114 and the integrated device 120 may include reaction chambers 132 (e.g., sample wells) configured to support (e.g., contain) a biological sample, with the excitation source 114 configured to illuminate the reaction chambers 132. In some embodiments, excitation of the biological sample may cause the sample to emit fluorescent light. In some embodiments, the integrated device 130 may include an array 124 of pixels 130 associated with respective reaction chambers 132 and/or groups of reaction chambers 132 with photodetectors 134 configured to generate and collect charge carriers in response to receiving the fluorescent light. Each pixel 130 may be configured to read out signals indicating collected charge carriers to one or more ADCs 126 to be digitized and offloaded from the integrated device 120 for processing. For example, the number of collected charge carriers may be used (e.g., in combination with a time of arrival of the charge carriers) to determine fluorescence information of the sample (e.g., fluorescence lifetime information).

In some embodiments, excitation light may also reach the photodetectors 134. The photodetectors 134 may be configured to separate and transfer, to a drain region, charge carriers generated in response to the excitation light. In some embodiments, such as described further herein, current output from drain regions of the pixel array 124 (e.g., from multiple pixels 130 receiving light from different portions of an optical component of the device 120) may be used to determine one or more positions on the integrated device 120 to be illuminated using the excitation light source 114. In some embodiments, such processing may be alternatively or additionally performed onboard the integrated device 120. FIG. 1 shows a single ADC 126, though it should be appreciated that multiple ADCs may be used, such as one ADC per quadrant of the pixel array 124, one ADC per row of the pixel array, one ADC per column of the pixel array, and/or one ADC per pixel of the pixel array 124, as embodiments described herein are not so limited.

In FIG. 1, control circuits 112, 122 are shown as part of the integrated device 120 and instrument 110 of the system 100, respectively, though some embodiments of the system 100 may include a single control circuit external to, and connected to, each of the integrated device 120 and/or instrument 110.

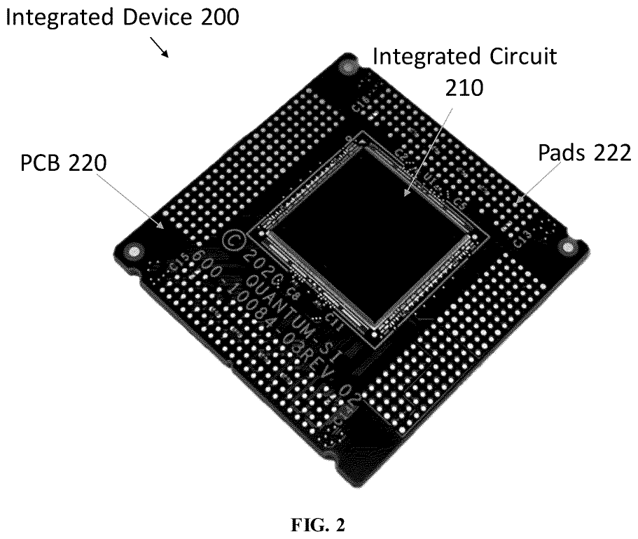

FIG. 2 is a perspective view of an example integrated device 200 that may be included in the system 100, according to some embodiments. As shown in FIG. 2, the integrated device 200 includes an integrated circuit 210 mounted on a printed circuit board (PCB) 220. In some embodiments, the integrated circuit 210 may be configured as an integrated photodetector. For example, the integrated circuit 210 may include a pixel array (e.g., 124) with photodetectors (e.g., 134) configured to detect incident light, such as by generating charge carriers in response to received photons. In some embodiments, the integrated circuit 210 may be positioned with respect to an excitation light source (e.g., 114) to cause excitation light to illuminate pixels of the integrated circuit 210. For example, the integrated circuit 210 may include an optical component (e.g., grating coupler) exposed through packaging of the integrated circuit 210 to receive excitation light. In some embodiments, a control circuit (e.g., 122) external to the integrated device 200 may be communicatively coupled to the integrated device 200 via pads 222 of the PCB 220 to control operation of the integrated device 200 and/or to obtain signals from the integrated device 200 (e.g., via ADCs 226). In other embodiments, a control circuit (e.g., 122) may be located onboard the integrated device 200, such as within the integrated circuit 210.

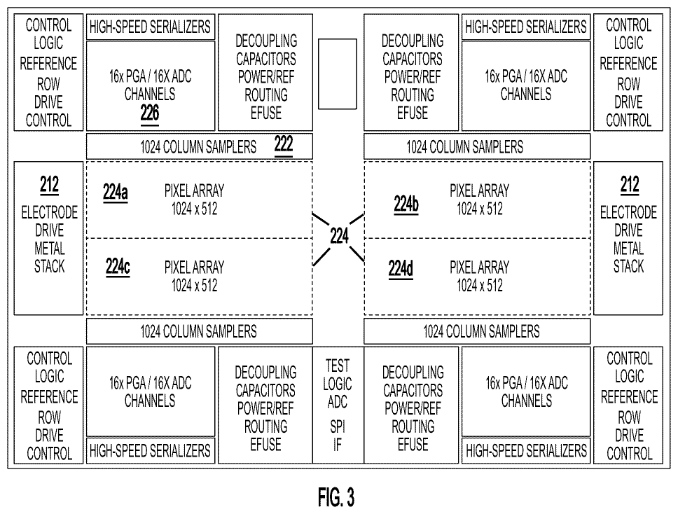

FIG. 3 is an annotated top view of the integrated circuit 210 of the integrated device 210, according to some embodiments. As shown in FIG. 3, the integrated circuit 210 may include a pixel array 224 having four pixel array quadrants 224a, 224b, 224c, and 224d. In other embodiments, pixels may be arranged in a lesser or greater number of sections (e.g., halves, octants), as embodiments are not so limited. Each pixel array quadrant 224a, 224b, 224c, and 224d may be sampled by a respective sampler circuit 225 (e.g., for each row or column of pixels) and provided to an ADC 226 for digitizing and offloading signals corresponding to light received by pixels of the quadrant. Pixels of, and/or within, each quadrant 224a, 224b, 224c, 224d may be operated at the same time using control signals provided via metal lines 212 of electrode drive metal stacks. Control signals provided to the pixels via the metal lines 212 may be generated on-chip and/or received from an external control circuit.

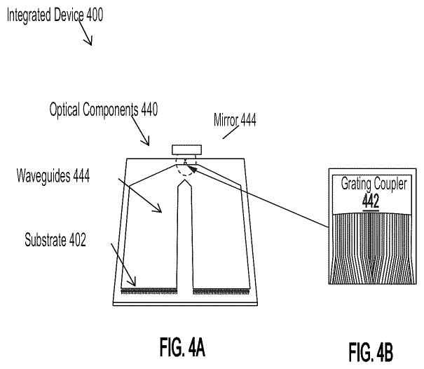

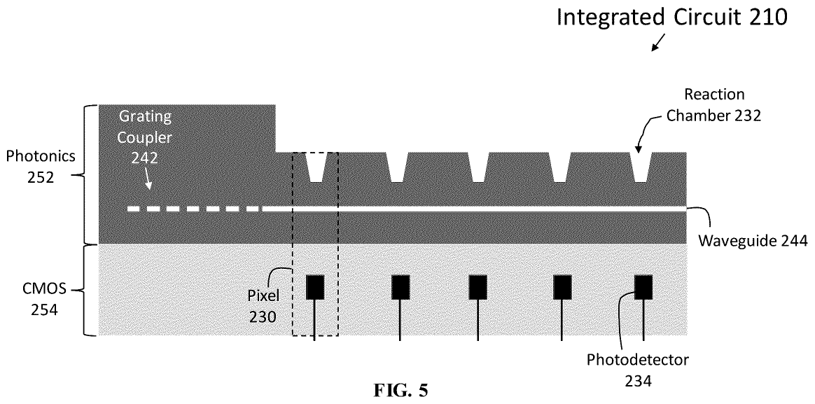

FIG. 4A is a top view of optical components 440 of an integrated device 400 that may be configured to deliver excitation light to pixels of the integrated device 400, according to some embodiments. In some embodiments, the integrated device 400 may be configured as described herein for the integrated device 200. As shown in FIG. 4A, optical components 440 of the integrated device 400 may include a grating coupler 442 and optical waveguides 444 extending from the grating coupler 442 toward the pixel array (e.g., 124, 224) of the integrated device 400. In some embodiments, the optical components 440 may further include a minor 444.

FIG. 4B is an enlarged top view of the grating coupler 442 of the integrated device 400, according to some embodiments. In some embodiments, when the integrated device 400 interfaces with an instrument (e.g., 110) having an excitation light source (e.g., 114), the excitation light source may be positioned to illuminate the grating coupler 442 so as to provide excitation light to excite samples in reaction chambers (e.g., 132) of pixels of the integrated device 400. In some embodiments, the optical waveguides 444 may split from one another to distribute excitation light to rows and/or columns of pixels of the integrated device 400 and/or within each section (e.g., quadrant) of the pixel array.

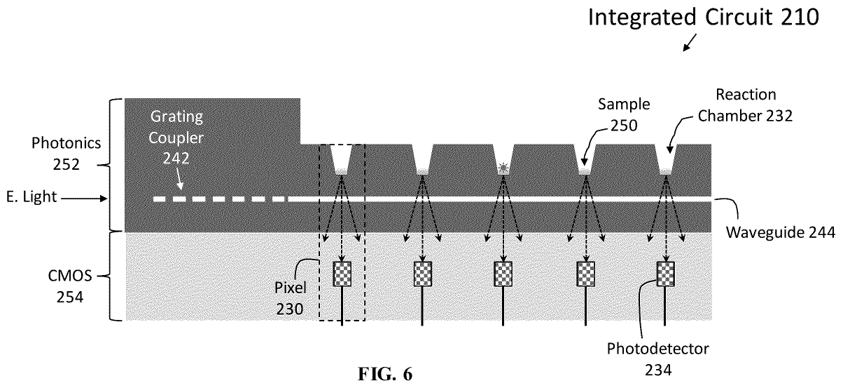

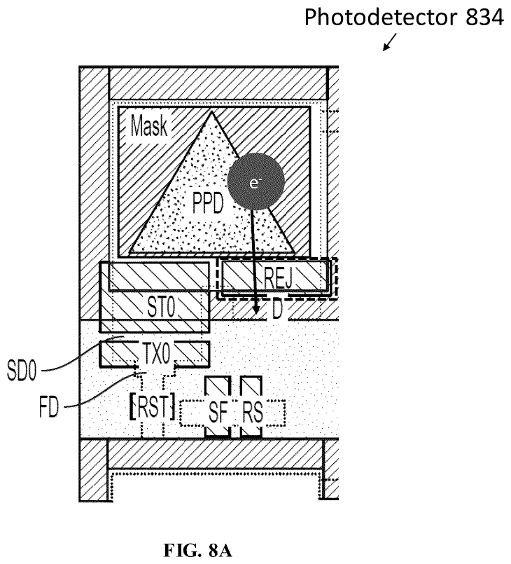

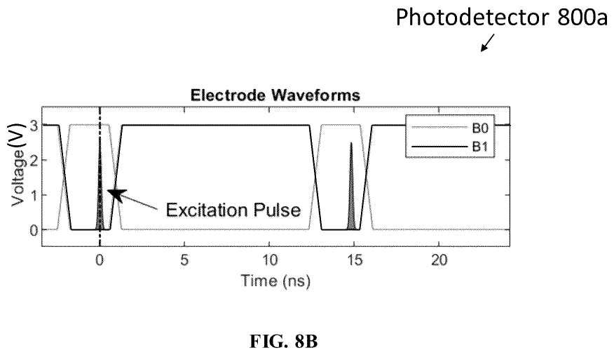

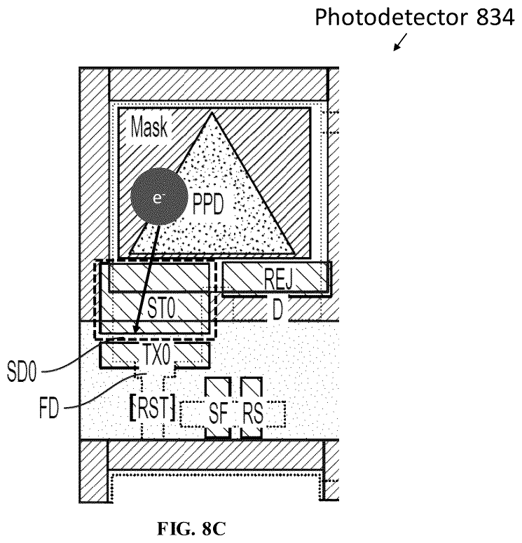

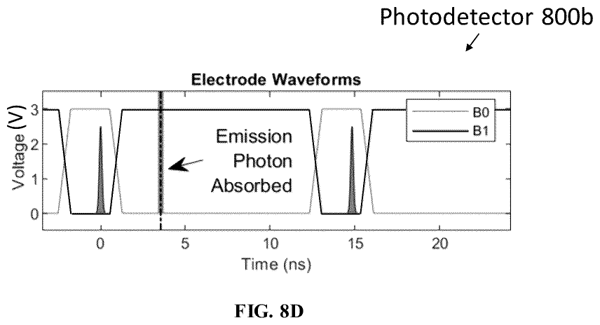

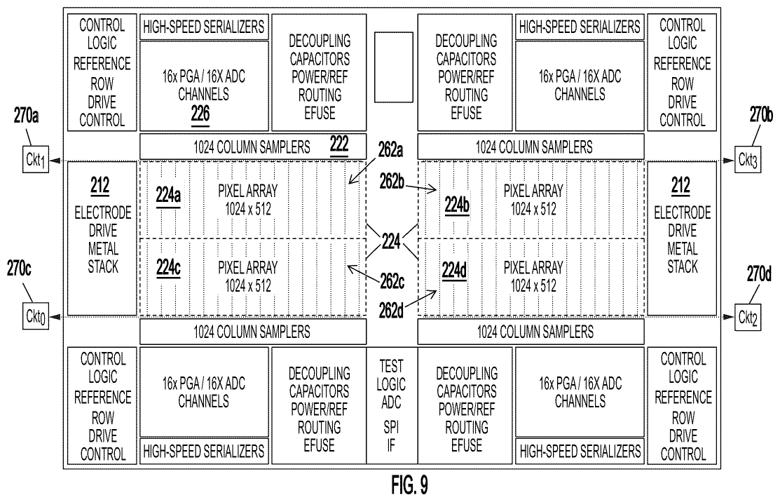

FIG. 5 is a cross-sectional view of a dimension of a pixel array of the integrated circuit 210, according to some embodiments. In some embodiments, the integrated circuit 210 may further have optical components configured as shown in FIG. 4, such as a grating coupler 242 and a waveguide 244. For example, as shown in FIG. 5, a waveguide 244 may be elongated along a dimension (e.g., row or column) of pixels 230 between reaction chambers 232 and photodetectors 234 of the pixels 230. In some embodiments, each pixel 230 has one or more reaction chambers 232 and one or more photodetectors 234 that correspond to and/or are associated with the reaction chamber(s) 232, as well as corresponding control circuitry (e.g., drain and charge storage transfer gates) and readout circuitry (e.g., source-follower transistor and row-select transfer gate) (see examples in FIGS. 7-8B). In the example illustrated in FIG. 5, each pixel has a single reaction chamber 232 and a single corresponding photodetector 234.

In some embodiments, the integrated circuit 210 may include multiple layers respectively configured, at least in part, for optics and electronics. For example, in FIG. 5, the integrated circuit 210 has a photonic layer 252 in which the grating coupler 242 and waveguide 244 are disposed and a complementary metal-oxide-semiconductor (CMOS) layer in which the photodetectors 234 are disposed.

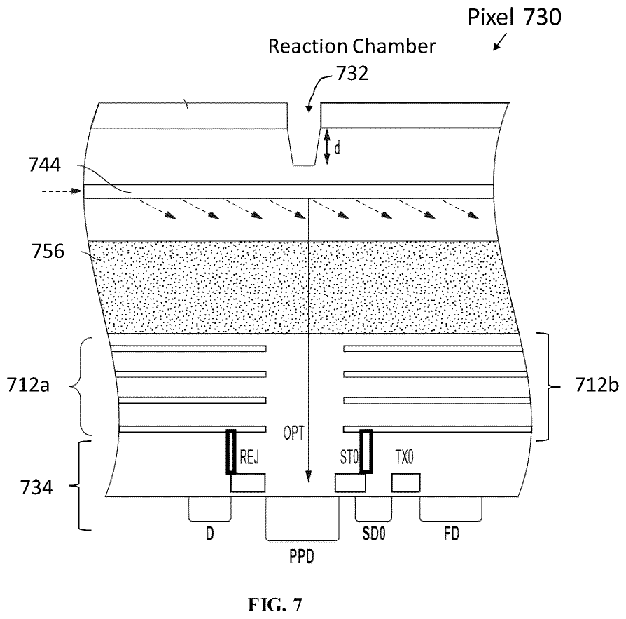

FIG. 6 is a cross-sectional view of the dimension of pixels of FIG. 5 illuminated with excitation light to excite a sample 250 in the reaction chambers 234, according to some embodiments. As shown in FIG. 6, excitation light propagating in the waveguide 244 may evanescently couple from the waveguide 244 to the reaction chambers 232 to excite fluorescence in the sample 250. Also shown in FIG. 6, the excitation light may also evanescently couple to the photodetectors 234. In some embodiments, the excitation light may reach the photodetectors 234 before the fluorescent light emitted by the sample 250 reaches the photodetectors 134. In some embodiments, the photodetectors 134 may be configured to drain charge carriers received in a first time period (e.g., during the excitation light pulse) and collect charge carriers received in a second time period (e.g., following the excitation light pulse) such that the drained charge carriers correspond substantially to excitation light and the collected charge carriers correspond substantially to fluorescent light.

The inventors have recognized that, while it may be disadvantageous for excitation light to reach the photodetectors 234 as it may add noise to measurements of fluorescent emissions, the arrival of excitation light at the photodetectors 234, which may be impossible to completely eliminate in some applications, may be advantageously leveraged, in some embodiments, to determine an illumination position on the integrated circuit 210, as described further herein.

FIG. 7 is a side view of a cross-section of a pixel 730 that may be included in the integrated device 200, according to some embodiments.

As shown in FIG. 7, the pixel 730 includes a reaction chamber 732 and a photodetector 734 with a photonic structure 756 and metal lines 712a, 712b disposed between the reaction chamber 732 and the photodetector 734. In some embodiments, the photonic structure 756 may be configured to block at least some excitation light from reaching the photodetector 734 while permitting fluorescent light to reach the photodetector 734, such as using wavelength discrimination (e.g., as fluorescent light may have a longer wavelength than excitation light in some embodiments).

Also shown in FIG. 7, the photodetector 734 includes a photodetection region, which may be a pinned photodiode (PPD), configured to receive light substantially in a direction OPT. For example, the photodetection region PPD may include a doped semiconductor region configured to generate charge carriers in response to receiving incident light. Also shown in FIG. 7, the photodetector 734 includes a charge storage region, which may be a storage diode (SD) SD0, configured to receive charge carriers from the photodetection region PPD. For example, in FIG. 7, a transfer gate ST0 is shown disposed at least in part between the photodetection region PPD and the charge storage region SD0. Also shown in FIG. 7, the photodetector 734 includes a drain region D, also configured to receive charge carriers from the photodetection region PPD using a transfer gate REJ disposed at least in part from the photodetection region PPD.

In some embodiments, the charge storage region SD0 may be configured to collect charge carriers to be read out of the photodetector 134. For example, as shown in FIG. 7, the charge storage region SD0 is coupled to a readout region, which may be a floating diffusion (FD) region. For instance, the photodetector 134 may be configured to transfer collected charge carriers from the charge storage region SD0 to the readout region FD to be sampled (e.g., using correlated double sampling) and digitized for processing of detected fluorescent light.

In some embodiments, the drain region D may be configured to draw charge carriers from the photodetection region PPD. For example, the drain region D may be configured to receive a bias voltage configured to draw charge carriers from the photodetection region PPD (e.g., a high voltage for photoelectrons or a low voltage for photo-holes). For instance, during an excitation light pulse, the transfer gate REJ may be controlled to transfer charge carriers from the photodetection region PPD to the drain region D such that, at a subsequent time when fluorescent light reaches the photodetection region PPD, the charge carriers generated in response to the excitation light do not pollute the charge carriers collected in the charge storage region SD0 corresponding to fluorescent light.

In some embodiments, a control circuit (e.g., 112) of the fluorescence detection system (e.g., 100) that includes the integrated device 200 may be configured to generate signals to control operation of each pixel. For example, the control circuit may be configured to provide control signals to the pixel 730 via metal lines 712a, 712b shown in FIG. 7. In the illustrated example, a first set of metal lines 712a connect to transfer gate REJ and a second set of metal lines 712-b connect to transfer gate ST0. In some embodiments, transfer gate ST0 may be configured to control charge carrier transfer from photodetection region PPD to charge storage region SD0 in response to the control signal received at transfer gate ST0 via the metal lines 712a. In some embodiments, transfer gate REJ may be configured to control charge carrier transfer from photodetection region PPD to drain region D in response to the control signal received at transfer gate REJ via the second set of metal lines 712b.

While the drain region D and the charge storage region SD0 are shown schematically on opposite sides of the photodetection region PPD, in some embodiments the drain region D and the charge storage region SD0 may be located on a same side of the photodetection region PPD.

While the metal lines 712a, 712b are shown in FIG. 7 between the reaction chambers 732 and the photodetectors 734, in other embodiments, the photodetectors may be disposed between the metal lines and the reaction chambers. For example, the illustrated embodiment may be configured for front-side illumination (FSI), though the techniques described herein may be implemented in a back-side illuminated (BSI) configuration as well.

FIG. 8A is a top view of a photodetector 834 that may be included in the integrated device 200 during an excitation light pulse, according to some embodiments. FIG. 8B is a graph of voltage over time at the transfer gates REJ and ST0 of the photodetector 834 superimposed with the timing of the excitation light pulse, according to some embodiments.

In some embodiments, an excitation light source (e.g., 114) may emit a pulse of excitation light to the integrated device (e.g., 200) to be propagated via waveguides (e.g., 244) to pixels (e.g., 230) of the integrated device. As shown in FIG. 8A, during an excitation light pulse, charge carriers (e.g., photoelectrons) may be generated in the photodetection region PPD corresponding to photons of the excitation light. In some embodiments, charge carriers generated in response to the excitation light may be transferred from the photodetection region PPD to the drain region D under the control of a control signal (e.g., B0 in FIG. 8B) applied to transfer gate REJ. For example, the control signal B0 shown in FIG. 8B has a high voltage level, during the excitation light pulse, that may bias a semiconductor channel proximate (e.g., underlying) transfer gate REJ to connect the drain region D to the photodetection region PPD and draw the charge carriers therebetween. In some embodiments, the drain region D may be configured to receive a bias voltage (e.g., from a bias path of the integrated circuit) that is attractive to the charge carriers generated in the photodetection region PPD, such that charge carriers are drawn to the drain region D from the photodetection region PPD while the control signal B0 controls the transfer gate REJ with a voltage level that biases the semiconductor channel proximate the transfer gate REJ to be conductive.

In some embodiments, at the time of the excitation pulse, the transfer gate ST0 may be configured to block charge carriers in the photodetection region PPD from reaching the charge storage region SD0. For example, in FIG. 8B, at the time of the excitation light pulse, the control signal B1 applied to the transfer gate ST0 has a voltage level opposite that of the control signal B0 applied to transfer gate REJ. In the illustrated example, a high control voltage may cause a transfer gate to bias an n-type semiconductor region to be conductive and thereby transfer charge carriers, whereas a low control voltage may cause a transfer gate to bias an n-type semiconductor region to be nonconductive and thereby block charge carrier transfer, though it should be appreciated that techniques described herein may be implemented in a p-type doped CMOS photodetector, for example, by changing the polarity of the voltage levels of the control signals B0 and B1.

FIG. 8C is a top view of the photodetector 834 during a fluorescent emission, according to some embodiments. FIG. 8D is a graph of voltage over time at the transfer gates REJ and ST0 of the photodetector 834 during the fluorescent emission, according to some embodiments.

In some embodiments, a sample excited by excitation light may emit one or more fluorescent photons of fluorescent light. As shown in FIG. 8C, a fluorescent photon may arrive at the photodetection region PPD from the sample, during which time, a charge carrier (e.g., photoelectron) corresponding to the fluorescence photon may be generated in the photodetection region PPD. In some embodiments, charge carriers generated in the photodetection region PPD in response to fluorescent light may be transferred from the photodetection region PPD to the charge storage region SD0 under the control of the control signal B1 applied to transfer gate ST0. For example, in FIG. 8D, the control signal B1 has a high voltage level, during the fluorescent emission, that may bias the semiconductor material proximate (e.g., underlying) the transfer gate ST0 to be conductive, to connect the charge storage region region SD0 to the photodetection region PPD and draw the charge carriers therebetween.

In some embodiments, at the time of the fluorescent emission, the transfer gate REJ may be configured to block charge carriers in the photodetection region PPD from reaching the drain region D. For example, in FIG. 8D, at the time of the fluorescent emission, the control signal B0 applied to the transfer gate REJ has a voltage level opposite that of the control signal B1 applied to transfer gate ST0.

In some embodiments, the timing of control signals B0 and B1 may be controlled to draw charge carriers, generated in the photodetection region PPD in response to excitation light, to the drain region D and to transfer charge carriers, generated in the photodetection region PPD in response to fluorescence light, to the charge storage region SD0. In some embodiments, control signals B0 and B1 may be repeatedly applied (e.g., periodically) to conduct a fluorescent measurement. For example, the measurement may include a pulse of the control signal B0 (e.g., at least partially coincident with an excitation light pulse) and a pulse of the control signal B1 (e.g., at least partially coincident with a fluorescent emission). In some embodiments, charge carriers, generated in response to fluorescent emissions over a plurality of measurements, may be aggregated in the charge storage region SD0. For example, each measurement may produce a number of charge carriers that is too small to read out (e.g., to satisfy a given signal-to-noise ratio constraint for downstream processing), and aggregating charge carriers over a plurality of measurements may produce a large enough signal to read out and use downstream (e.g., to determine a fluorescence lifetime).

In some embodiments, a series of measurements (e.g., pairs of pulses of B0 and B1 signals) may have a different timing of the B1 control signal pulse with respect to the B2 control signal pulse and/or with respect to the excitation light pulse. For example, a first series of measurements may have a first timing of the B1 and/or B2 control signals with respect to the excitation light pulse and a second series of measurements may have a second timing, different from the first timing, with respect to the excitation light pulse. For instance, using different timings in this manner may result in different collection timings with respect to the excitation light pulse, potentially causing a different amount of fluorescent photons to be detected during the collection period (e.g., as fluorescent emissions typically follow an exponentially decaying probability curve). In some embodiments, the different amounts of fluorescent emissions detected using different timings of the control signals B0 and/or B1 with respect to the excitation light pulse may be used (e.g., as a ratio indicating a rate of exponential decay) to determine a fluorescent lifetime of the sample.

FIGS. 8A and 8C further illustrate readout circuitry of the photodetector 834, including a source follower (SF) gate, a row select (RS) gate, and a reset (RST) gate. In some embodiments, the SF gate may be configured to sample charge carriers from the readout region FD when the RS gate is controlled to transfer the charge carriers to a sample circuit (e.g., 222). In some embodiments, the RST gate may be configured to reset a voltage of the readout region FD when the RST gate connects the readout region FD to a reset voltage.

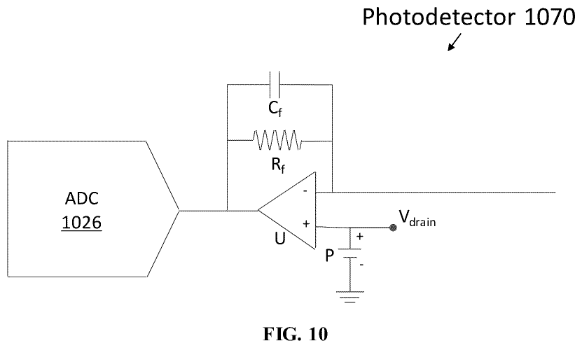

While a single charge storage region and drain region are shown in the illustrated example, it should be appreciated that multiple charge storage regions and/or drain regions per pixel may be used, as embodiments described herein are not so limited. As one example, two charge storage regions positioned side-by-side proximate the photodetection region PPD may be operated with respective control signals (e.g., versions of B1 in FIGS. 8B and 9B) having different timings with respect to the excitation. In the same or another example, a charge storage region may be sequentially coupled between charge storage region SD0 and the readout region FD.

### III. Pixel Current Measurement Techniques

FIG. 9 is a top view of an example configuration of the integrated circuit 210 superimposed with lines representing optical components 262a, 262b, 262c, and 262c that may be configured to provide excitation light to pixel array quadrants 224a, 224b, 224c, and 224d, respectively, of the integrated circuit 210, according to some embodiments.

In some embodiments, the optical components 262a, 262b, 262c, 262d may include waveguides (e.g., 244) optically coupled to portions of a grating coupler (e.g., 242) to deliver light from the grating coupler to the pixels (e.g., 230) to illuminate a sample supported in the reaction chambers (e.g., 232). In the example embodiment illustrated in FIG. 9, the illustrated optical components 262a, 262b, 262c, and 262d are shown arranged in four groups superimposed over the respective pixel array quadrants 224a. 224b, 224c, and 224d. For example, each pixel array quadrant 224a, 224b, 224c, and 224d may be configured to receive excitation light from the respective group 262a, 262b, 262c, 262d of the optical components shown superimposed over that pixel array quadrant.

In some embodiments, optical components configured to deliver excitation light to pixels in some or each of the pixel array quadrants may be coupled to different portions of a grating coupler. For example, the optical components 262a and 262c shown superimposed over pixel array quadrants 224a and 224c may be optically coupled to portions on a first side of the grating coupler and the optical components 262b and 262d shown superimposed over pixel array quadrants 224b and 224d may be optically coupled to portions on a second side of the grating coupler. It should be appreciated that other configurations of optical components optically coupled to respective regions of the grating coupler are possible, as embodiments described herein are not so limited.

In some embodiments, the integrated circuit 210 may further include a plurality of measurement circuits coupled to a respective pixel group (e.g., quadrant). For example, as shown in FIG. 9, measurement circuit 270a, 270b, 270c, and 270d are shown coupled to respective pixel array quadrants 224a, 224b, 224c, and 224d. In some embodiments, each measurement circuit 270a, 270b, 270c, and 270d may be configured to bias drain regions (e.g., D) of at least some pixels of the respective pixel array quadrants 224a, 224b, 224c, 224d to draw charge carriers from the photodetection region (e.g., PPD) to the drain region (e.g., when a control signal B0 controls the transfer gate REJ to do so). In some embodiments, charge carriers drawn along bias paths from the pixels to the corresponding measurement circuits 270a, 270b, 270c, and 270d may be measured as output currents, which as described further below, may be used to determine an illumination position on the integrated circuit 210. It should be appreciated that any number of measurement circuits may be used, for example corresponding to the number of groups (e.g., quadrants) of pixels in the pixel array 224.

In some embodiments, current measured using the measurement circuits 270a, 270b, 270c, and/or 270d may indicate an amount of current output from the respective pixel array quadrant 224a, 224b, 224c, and/or 224d. For instance, such measured current may indicate an amount of current output from all pixels of the pixel array quadrant, and/or a subset of pixels of the pixel array quadrant, such as a single pixel, as embodiments described herein are not so limited. In some embodiments, currents measured using measurement circuits 270a and 270c may indicate currents output from pixel array quadrants 224a and 224c, respectively, which in turn may be configured to receive excitation light from portions of the first side of the grating coupler, and are thus sensitive (e.g., more sensitive than the pixel array quadrants 224b and 224d) to excitation light received at the first side of the grating coupler. Likewise, currents measured using measurement circuits 270b and 270d may indicate currents output from the pixel array quadrants 224b and 224d, which in turn may be configured to receive excitation light from portions on the second side of the grating coupler, and are thus sensitive (e.g., more sensitive than the pixel array quadrants 224a and 224c) to excitation light received at the second side of the grating coupler.

In some embodiments, a difference in sensitivity of pixels and/or pixel array quadrants to excitation light received at different portions of an optical component, such as the grating coupler 242, may be used to determine an illumination position on the integrated circuit 210 (e.g., such as on the grating coupler 242). For example, portions of an optical component (e.g., grating coupler 242) may be offset from one another. For instance, in the example described above in which the optical components 262a and 262b may be configured to receive excitation light from portions on respective first and second of the grating coupler 242, the portions on the first and second sides may be offset from one another, such as a direction along which the first side is separated from the second side.

In some embodiments, a combination of (e.g., difference between) current measurements from multiple measurement circuits (e.g., 270a and 270b) may indicate alignment of the excitation light source (e.g., 114) and the integrated device 200, such as alignment of the excitation light source and the integrated circuit 210. For example, more measured current from measurement circuit 270a than measurement circuit 270b may indicate that the excitation light source is illuminating a position on the integrated circuit 210 (e.g., on the grating coupler 242) that is on centered on the first side. For instance, such an illumination position may result in more excitation light reaching the optical components that feed excitation light to the pixel array quadrants 224a and 224c, in the configuration of FIG. 9, than excitation light that reaches the optical components that feed the pixel array quadrants 224b and 224d. In such a case, the illumination position may be adjusted (e.g., by moving the integrated device 200 relative to the excitation light source and/or vice versa) and further measurements taken until an illumination position is determined that is centered substantially between the first and second sides of the optical component, which may be a desirable alignment of the excitation light source and integrated circuit 210.

It should be appreciated that as many or as few pixels (e.g., a single pixel) may be coupled to a measurement circuit as dictated by the particular application. For example, coupling a large number of pixels to a measurement circuit may produce a large amount of current suitable for a measurement circuit with low sensitivity, whereas some applications may be able to use current from a single pixel (e.g., by integrating the current in a capacitor or other suitable technique).

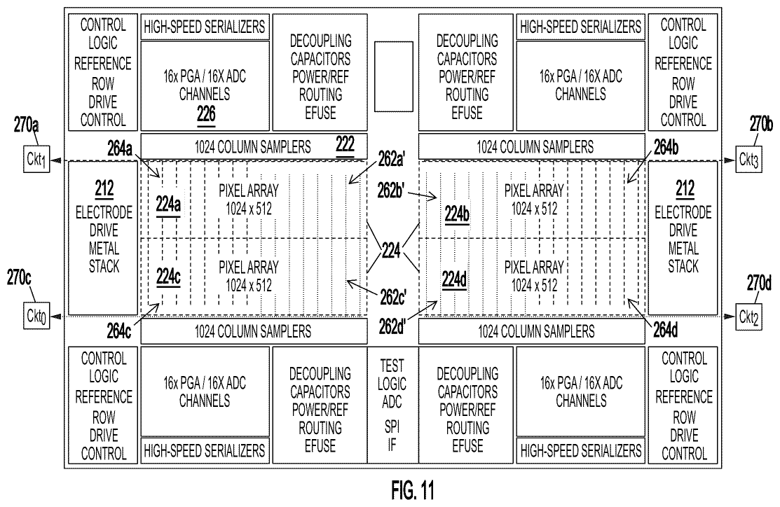

FIG. 10 is a circuit diagram illustrating an example measurement circuit 1070 that may be included in the integrated circuit 210, according to some embodiments. In some embodiments, the measurement circuit 1070 may be included in the configuration shown in FIG. 9 as any or each of the measurement circuits 270a, 270b, 270c, and/or 270d.

As shown in FIG. 10, the measurement circuit 1070 includes a transimpedance amplifier (TIA) that includes an amplifier U with a feedback resistor R_{f} and a feedback capacitor C_{f} coupled in parallel between the inverting input (−) of the amplifier U and the output of the amplifier. In FIG. 10, the noninverting input (+) of the amplifier U is shown configured to receive a drain voltage V_{drain}, which may be a high voltage (e.g., where the photodetection regions of the pixels are configured to generate charge carriers as photoelectrons) provided by a power supply P of the integrated device (e.g., 200). In the illustrated example, the inverting input (−) of the amplifier may be configured for coupling to drain regions (e.g., D) of pixels of the integrated device via metal lines (e.g., 712a). In some embodiments, the illustrated TIA may be configured to bias the drain regions of the pixels to which the measurement circuit 1070 is coupled with the voltage V_{drain}, which may draw charge carriers from the photodetection regions of the pixels to the drain regions of the pixels (e.g., when the control signal B0 applied to the transfer gate B0 controls it to do so). In some embodiments, the illustrated TIA may be further configured to receive current (e.g., negative current due to flow of photoelectrons from the drain regions) and convert the current to a voltage using the resistor R_{f} and capacitor C_{f}. Further shown in FIG. 10, the measurement circuit 1070 includes an ADC coupled to the output of the TIA, which may be configured to digitize the voltage from the TIA into a digital signal representing the amount of current output from the pixel(s) to which the noninverting input of the amplifier may be coupled. In some embodiments, the digitized voltage may be offloaded from the integrated circuit 210 to a processor, which in turn may be configured to determine an illumination position on the integrated photodetector using the digitized voltage (e.g., as indicative of a current measurement).

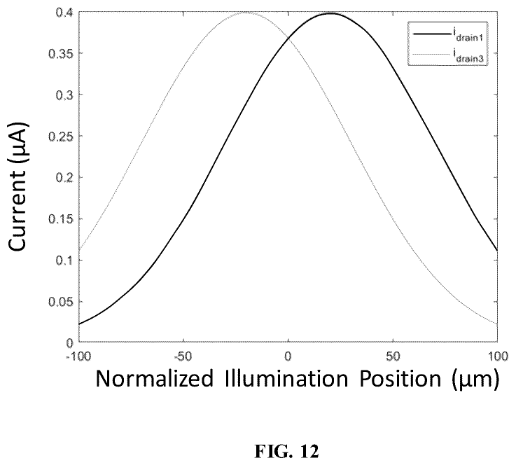

FIG. 11 is a top view of an alternative example configuration of the integrated circuit 210 superimposed with lines representing optical components 262a′, 262b′, 262c′, 262d′, 264a, 264b, 264c, and 264d, that may be configured to provide excitation light to groups of pixels of the integrated circuit 210, according to some embodiments.

Similar to the configuration shown in FIG. 9, the configuration in FIG. 11 includes optical components (e.g., waveguides) 262a′, 262b′, 262c′, and 262d′ superimposed over respective pixel array quadrants 224a, 224b, 224c, and 224d. In contrast to the configuration of FIG. 9, optical components 264a, 264b, 264c, and 264d are further shown superimposed over respective pixel array quadrants 224a, 224b, 224c, and 224d. For example, within each pixel array quadrant (e.g., 224a), some pixels may be configured to receive excitation light via (e.g., optically coupled to) a first group of optical components (e.g., 262a′) from a first portion of the grating coupler (e.g., 242) whereas other pixels may be configured to receive excitation light via (e.g., optically coupled to) a second group of optical components (e.g., 264a) from a second portion of the grating coupler (e.g., 242).

In some embodiments, portions of optical components (e.g., grating coupler 242) that are configured to provide excitation light to respective pixels or groups of pixels may be offset from one another in multiple directions. For example, at least some optical components shown in FIG. 11 (e.g., 262a′ and 262b′) may be configured to receive excitation light from portions of the grating coupler 242 that are offset from one another in a first direction (e.g., a direction substantially perpendicular to a direction of light incident from the excitation light source), and at least some optical components shown in FIG. 11 (e.g., 262a′ and 264a) may be configured to receive excitation light from portions of the grating coupler 242 that are offset from one another in a second direction (e.g., substantially perpendicular to the first direction and a direction of incident excitation light).

In some embodiments, the measurement circuits 270a, 270b, 270c, and 270d in the configuration of FIG. 11 may be configured to receive current output from pixels of multiple pixel array quadrants. For example, as shown in FIG. 11, measurement circuit 270a may be coupled to drain regions of a first subset of pixels of pixel array quadrants 224a and 224c, that are configured to receive excitation light from portions of the grating coupler 242 that are substantially aligned. At the same time, as shown in FIG. 11, the portions of the grating coupler 242 from which the first subset of pixels may be configured to receive excitation light may be offset (e.g., in a first direction) from portions of the grating coupler 242 from which other pixels of the pixel array quadrants 224a and 224c are configured to receive excitation light, and further may be offset from portions of the grating coupler from which the pixels of pixel quadrants 224b and 224d are configured to receive excitation light (e.g., in a second direction). While measurement circuits 270a and 270c are shown coupled to pixels of multiple pixel array quadrants 224a and 224c and measurement circuits 270b and 270d are shown coupled to pixels of multiple pixel array quadrants 224b and 224d, embodiments described herein are not so limited, as the pixels and optical components (e.g., waveguides, grating coupler) may be disposed in various arrangements.

In some embodiments, the grating coupler 242 may have first and second regions (e.g., quadrants) located on a first side of the grating coupler 242 and third and fourth regions (e.g., quadrants) located on a second side of the grating coupler 242, with the first and second sides separated along the first direction, the first and second regions (e.g., on a third side) separated along the second direction, and the third and fourth regions (e.g., on a fourth side) separated along the second direction. For example, optical components 262a′ and 262c′ may be configured to receive excitation light from the first region, optical components 264a and 264c may be configured to receive excitation light from the second region, optical components 262b′ and 262d′ may be configured to receive excitation light from the third region, and optical components 264b and 264d may be configured to receive excitation light from the fourth region.

In some embodiments, an illumination position of the excitation light source on the integrated photodetector may be determined in at least first and second directions using a combination of (e.g., difference between) amounts of current measured using at least some of the measurement circuits 270a, 270b, 270c, and 270d. For instance, in the illustrated example configuration of FIG. 11, more current being measured at measurement circuit 270a than at measurement circuit 270b may indicate that the excitation light source is illuminating a position on the grating coupler 242 that is centered closer to the first side of the grating coupler 242 (e.g., having the first and second regions in the above example) than to the second side of the grating coupler (e.g., having the third and fourth regions in the above example). Similarly (e.g., in the same measurement), measurement circuit 270c measuring more current than measurement circuit 270a may indicate that the excitation light source is illuminating a position on the grating coupler 242 that is centered closer to a third side (e.g., having the first and third regions in the above example) than to a fourth side (e.g., having the second and fourth regions in the above example). Accordingly, in this example, measurements from at least three pixels or groups (e.g., quadrants and/or subsets of quadrants) of pixels configured to receive excitation light from (e.g., optically coupled to) optical components offset in at least two directions and/or groups may be used to determine the illumination position on the integrated photodetector in at least two directions.

### IV. Illumination Position Determination

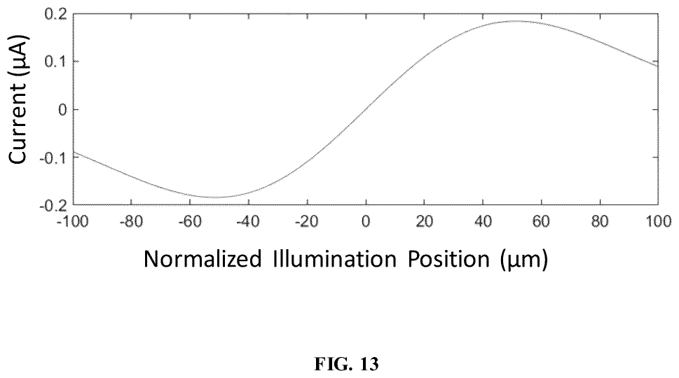

FIG. 12 is a graph of current amplitude vs. normalized illumination position for currents I_{drain1} and I_{drain3} that may be output from respective pixels and/or pixel array quadrants (e.g., 224a and 224b) of an integrated circuit (e.g., 210) and measured using respective measurement circuits (e.g., 270a and 270b), respectively, over an illumination sweep in a first direction, according to some embodiments.

In some embodiments, the amount of current measured by each measurement circuit (e.g., 270a and 270b) may have a peak current amplitude at a point, in the first direction, where the excitation light is centered on portions of the optical component (e.g., grating coupler 242) that are optically coupled to the respective pixels or groups of pixels (e.g., 224a and 224b). For example, as shown in FIG. 12, in the peak current amplitudes of measured current from the measurement circuits (e.g., 270a and 270b) are offset in the first direction, which may be due to the portions of the optical component (e.g., grating coupler 242) that are optically coupled to the respective pixels or groups of pixels (e.g., 224a and 224b) being offset in the first direction. For example, the peak current amplitude of measured current I_{drain1} may correspond to an illumination position centered, in the first direction, on the portions of the grating coupler 242 that deliver light to the pixel array quadrant 224a, and the peak current amplitude of measured current I_{drain3} may correspond to an illumination position centered, in the first direction, on the portions of the grating coupler 242 that deliver light to the pixel array quadrant 224b.

In some embodiments, the illumination position may indicate substantial alignment between the excitation light source (e.g., 114) and the integrated circuit (e.g., 210) in the first direction where the current amplitudes of the measured currents I_{drain1} and I_{drain3} are substantially equal, which is shown in FIG. 12 as a point substantially equidistant from and between the two current amplitude peaks (e.g., resulting in substantially equal current measured at the measurement circuits). In other cases, the point may not be substantially equidistant from the two current amplitude peaks, such as where the two current amplitude peaks are not equal in current amplitude. In the illustrated example, the point of substantial alignment may be at position zero, as the illustrated graph may be normalized to the point of substantial alignment.

It should be appreciated that similar techniques may be used to determine an illumination position based on current measured by measurement circuits 270c and 270d in the example of FIG. 9. Alternatively or additionally, measurements of currents from measurement circuits 270a and 270c may be summed and measurements of currents from measurement circuits 270b and 270d may be summed prior to illumination position determination (e.g., with current I_{drain1} corresponding to a sum of measurements from measurement circuits 270a and 270c and current I_{drain3} corresponding to a sum of measurements from measurement circuits 270b and 270d).

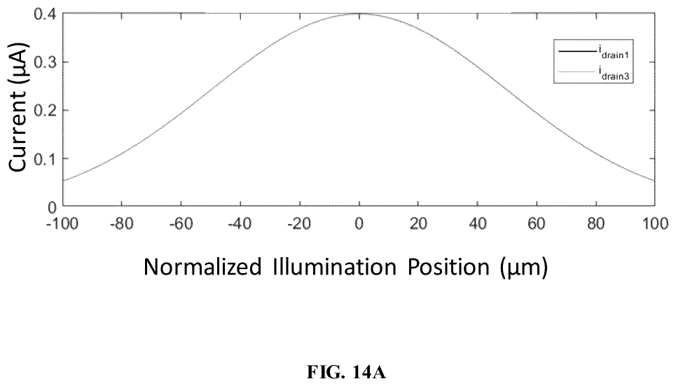

FIG. 13 is a graph of current amplitude vs. normalized illumination position for a difference between the measured currents I_{drain1} and I_{drain3} of FIG. 12, according to some embodiments.

As shown in FIG. 13, the absolute value of the difference between the measured currents I_{drain1} and I_{drain3} reaches a substantial minimum at the point, in a first direction, substantially equidistant from and between the two current amplitude peaks. As mentioned above, the substantial minimum difference may not be equidistant from the two current amplitude peaks, such as where the current amplitude peaks have different current amplitudes. In some embodiments, the substantial minimum point of the difference between measured currents from measurement circuits coupled to pixels or groups of pixels configured to receive excitation light from portions of an optical component that are offset in the first direction, may be determined to be an illumination position on the integrated circuit in alignment with the excitation light source.

In some embodiments, a processor of a fluorescence detection system (e.g., 100) may be configured to receive signals (e.g., digital signals) from measurement circuits of the integrated device (e.g., 200) indicating current measurements, such as those shown in FIGS. 12-13, and determine an illumination position therefrom. For example, the processor(s) may be configured to determine (e.g., select) the illumination position corresponding to the substantial minimum absolute value of the difference between measured currents. In some embodiments, the substantial minimum absolute value of the difference may be identified within a predetermined range of values (e.g., close to but not necessarily exactly zero). In some embodiments, the processor(s) may be configured to control and/or adjust the illumination position (e.g., by controlling a mechanism to position the excitation light source and/or integrated photodetector) to the determined illumination position. In some embodiments, the substantial minimum absolute value of the difference may be the minimum absolute value attainable based on a set of possible discrete motor steps for the mechanism, where the value may be nonzero.

In some embodiments, a processor of a fluorescence detection system (e.g., 100) may be configured to determine an illumination position using the integrated device configuration shown in FIG. 11 in a manner similar to how the illumination position may be determined in the first direction of FIG. 9. For example, a first excitation light sweep of the integrated device in the first direction may result in a graph of measured currents from measurement circuits 270a and 270b (and/or measurement circuits 270c and 270d) similar to the example of FIG. 9, where each current measurement has a current amplitude peak offset from the other current amplitude peak in the first direction. In some embodiments, a second excitation light sweep of the integrated device in a second direction (e.g., at each point that was also swept in the first direction) may result in measured currents from measurement circuits 270a and 270c (and/or measurement circuits 270b and 270d), which may resemble the measured currents shown in the graphs of FIGS. 12-13 (e.g., with current amplitude peaks offset in the second direction). In some embodiments, the processor(s) may be configured to compare and/or subtract current measurements obtained during the second sweep from one another to determine which current measurement is larger in magnitude, which may indicate whether and/or to what extent the illumination position is substantially misaligned in the second direction.

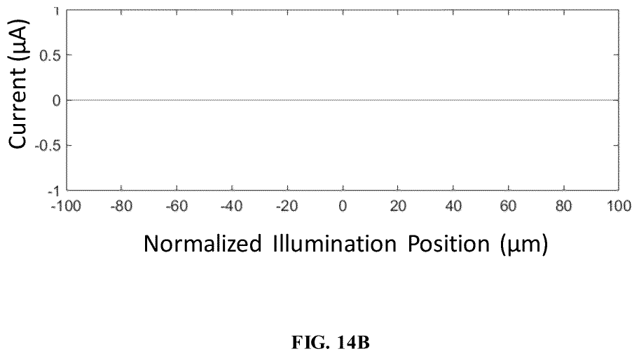

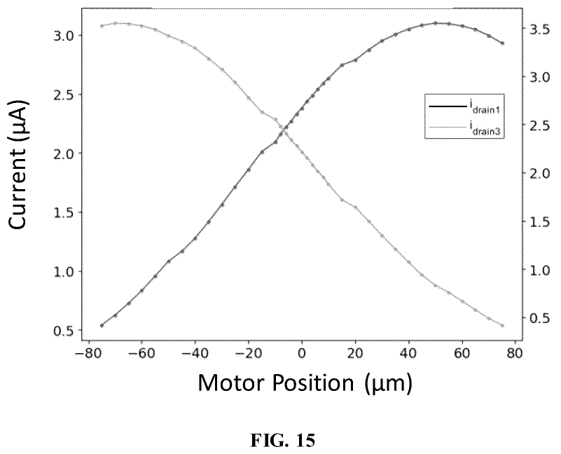

FIG. 14A is a graph of current amplitude vs. normalized illumination position for measured currents I_{drain1} and I_{drain3} that may be output from respective pixels or groups of pixels (e.g., pixel array quadrants 224a and 224c) of an integrated circuit (e.g., 210) and measured using respective measurement circuits (e.g., 270a and 270c), respectively, over an illumination sweep in a second direction, according to some embodiments. FIG. 14B is a graph of current amplitude vs. normalized illumination position for a difference between the measured currents I_{drain1} and I_{drain3} of FIG. 14B, according to some embodiments.

As shown in FIGS. 14A-14B, the measured currents I_{drain1} and I_{drain3} may be substantially equal (e.g., having substantially no difference in current amplitude) at each point of the illumination sweep in the second direction. In some embodiments, an illumination sweep in the second direction may be performed, after a first illumination position has been determined using a sweep in the first direction, to determine a second illumination position that has a substantial maximum measured current amplitude. It should be appreciated that other iterative techniques may be used, such as performing one or more illumination sweeps in the second direction prior to and/or interspersed with one or more illumination sweeps in the first direction.

In some embodiments, a sweep may be performed in the first direction, followed by a determination of whether and/or which of the measurement circuits (e.g., 270a and 270c), coupled to pixels configured to receive excitation light from portions of the optical component (e.g., grating coupler 242) that are offset in the second direction, measures more current, followed by another sweep in the first direction shifted appropriately in the second direction, until an illumination position has been determined to substantially minimize the difference in measured current amplitude across all measurement circuits (e.g., 270a, 270b, 270c, and 270d). It should be appreciated that other processing techniques and/or orders of sweeps may be used. It should also be appreciated that full sweeps may not be performed, as partial sweeps and/or individual illumination positions (e.g., at predetermined irregular intervals) may be performed, followed by shifting the illumination position based on current measurements (e.g., in the direction determined to result in reduced difference in measured current from the measurement circuits).

In some embodiments, illumination position sweeps and measurement of current may be performed at the start of a fluorescence detection measurement cycle (e.g., prior to performing any measurement series) and/or upon device startup as, and/or as part of, a calibration procedure.

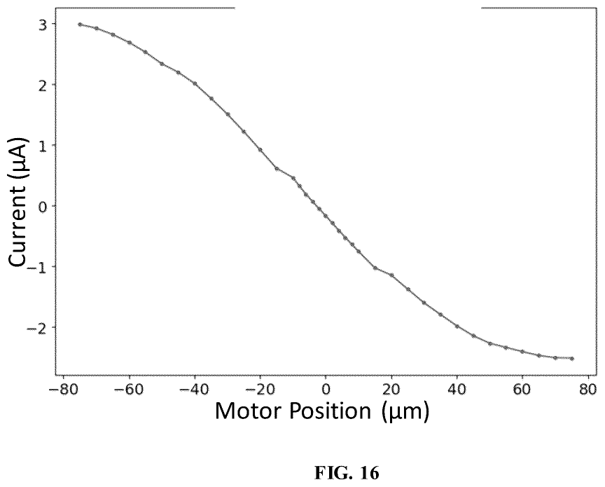

FIG. 15 is a graph of current amplitude vs. motor position for currents I_{drain1} and I_{drain3} measured from measurement circuits of an integrated circuit in response to a motor-driven illumination sweep in a first direction, according to some embodiments. As shown in FIG. 15, the illumination sweep in the first direction was performed using discrete motor steps, in microns, on a surface of the integrated circuit. For example, in this case, the motor controlled a stage controlling the relative positioning of the excitation light source and the integrated photodetector by positioning the excitation light source and the integrated photodetector with respect to one another. As shown in the graph, the measured currents have peak current amplitudes that are offset in the first direction, similar to FIG. 12.

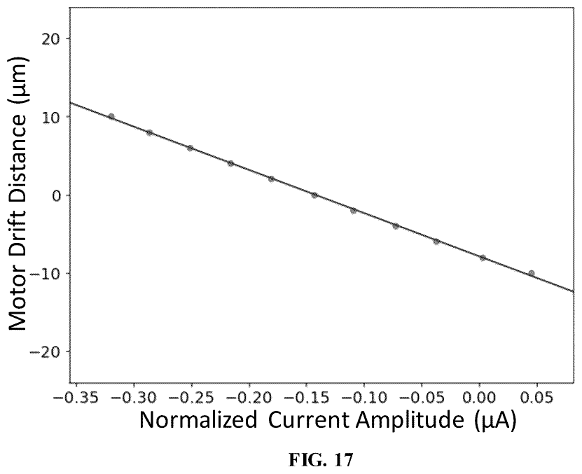

FIG. 16 is a graph of current amplitude vs. motor position for a difference between the measured currents I_{drain1} and I_{drain3} shown in FIG. 15, according to some embodiments.

As shown in FIG. 16, the difference between the measured currents I_{drain1} and I_{drain3} was substantially linear within the region of +/−50 microns. In some embodiments, an illumination position may be determined using the measured currents I_{drain1} and I_{drain3} of FIGS. 15 and 16 by selecting the motor position corresponding to the minimum absolute value of the difference between current amplitudes of the measured currents I_{drain1} and I_{drain3}, such as described above in connection with FIGS. 12 and 13. In some embodiments, a processor of a fluorescence detection system (e.g., 100) may be configured to control an illumination position on an integrated circuit (e.g., 210) based, at least in part, on measured currents from the integrated circuit, such as by executing a feedback control system. For example, the substantially linear response shown in FIG. 16 may be used as part of a linear feedback control system that outputs a motor position (e.g., using a motor movement control signal) in response to measured currents (e.g., I_{drain1} and I_{drain3}) as inputs.

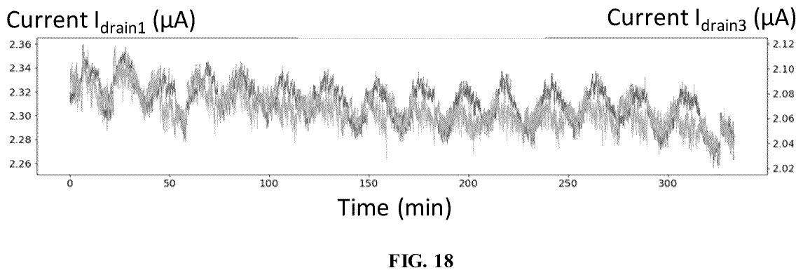

FIG. 17 is a graph of motor drift distance vs. normalized current amplitude for the difference between the measured currents I_{drain1} and I_{drain3} of FIG. 16, according to some embodiments.

In some embodiments, the difference in normalized measured currents I_{drain1} and I_{drain3} shown in FIG. 17 may be used by a processor of a fluorescence detection system (e.g., 100) to determine an amount of motor drift distance indicated by a measured difference in normalized currents from an integrated circuit (e.g., 210), which may assist the processor in determining whether and/or to what extent to adjust the illumination position on the integrated circuit. The graph in FIG. 17 was generated by normalizing (e.g., by the largest amplitude value) the measured current amplitude from each measurement circuit (e.g., 270a, 270b, 270c, 270d) to account for differences in peak measured current amplitude (e.g., at a relative position of substantial alignment between the excitation light source and the integrated circuit). Then, the difference was obtained by subtracting the normalized measured currents from one another. In the illustrated case, currents from some measurement circuits (e.g., 270a and 270c) may have been combined to result in only two current measurements for a difference to be taken.

In some embodiments, similar data to that shown in FIG. 17 may be obtained using an illumination sweep in a second direction using the configuration of FIG. 11 and currents measured using measurement circuits 270a and 270c and/or measurement circuits 270b and 270d. In some embodiments, normalized current differences may be used as shown in FIG. 17 or in a similar manner (e.g., taking into account differences between more than two current measurements) in determining an illumination position.

Also shown in FIG. 17 is a linear approximation superimposed over the values of difference in normalized measured current amplitude. In some embodiments, a linear approximation may be used in this or similar manner (e.g., depending on the error of the linear fit) to determine substantial misalignment and/or corresponding adjustments to the illumination position. For example, a processor may be configured to, in response to determining (e.g., within a feedback control system) that the difference in normalized measured current amplitude has a particular nonzero value, select a motor drift distance using the linear approximation (e.g., for use within a linear feedback control system). In some embodiments, a linear approximation may be used in a second direction, such as using the configuration of FIG. 11.

In some embodiments, a processor of a fluorescence detection system (e.g., 100) may be configured to execute a feedback control system (e.g., automatic and/or continuously operating) that receives current measurements from an integrated circuit and responsively adjusts an illumination position on the integrated circuit. For example, a (e.g., linear) feedback control loop may be executed using current measurements as feedback for illumination position with proportional control (e.g., linear gain from the linear approximations described above), though other feedback control loop models may be used.

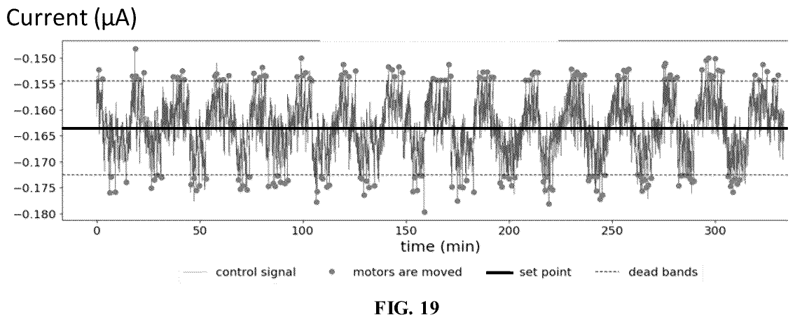

FIG. 18 is a graph of current amplitude vs. time for measured currents I_{drain1} and I_{drain3} from respective measurement circuits of an integrated circuit, according to some embodiments. The current amplitudes shown in FIG. 18 were measured continuously while the illumination position was adjusted in response to the current measurements (e.g., using a feedback control system executed by a processor). As shown in FIG. 18, the measured currents oscillated and differed from one another in amplitude over time. The observed oscillations may occur, for example, due to ordinary variations in ambient temperature as a result of HVAC cycling within a temperature regulated (e.g., air-conditioned) environment. In some embodiments, it may be desirable to periodically (e.g., using a feedback control system) determine and/or adjust the illumination position on the integrated circuit due to potential changes in alignment, which may be due to HVAC cycling or any other disturbance that may be present in the environment in which the fluorescence detection system operates.

FIG. 19 is a graph of normalized current amplitude vs. time for a difference between the normalized current measurements of FIG. 18, according to some embodiments. As shown in FIG. 19, the illumination position was adjusted at various points in time (shown by dots in FIG. 19) using a motor controlled in response to the current measurements. Due to the feedback loop employed (e.g., linear approximation model), the illumination position was adjusted when the change in the difference between the measurements of current exceeded one step of the motor. However, other configurations may be used depending on the tolerated extent of misalignment and/or available motor precision in the system.

In some embodiments, current measurements described herein may be used continuously during operation of an integrated device (e.g., 200) to account for substantial misalignment due to changes in the operating environment (e.g., ambient and/or device temperature).

In some embodiments, a processor (e.g., onboard and/or coupled to the integrated device and/or the excitation light source) may be configured to receive current measurements (e.g., in digital form) and/or determine an illumination position on the integrated circuit based, at least in part, on the measurements. In some embodiments, the processor may be configured to control the timing, and/or illumination position on the integrated photodetector, of an excitation light source (e.g., 114). In some embodiments, a non-transitory computer-readable medium may have instructions encoded thereon that, when executed a processor, cause the processor to perform such techniques.

It should be appreciated that an integrated photodetector may have more than one illumination position. For example, an excitation light source or multiple such sources may be configured to illuminate multiple (e.g., disjoint) locations on an integrated photodetector. In this example, an integrated photodetector may have multiple light-receiving optical components (e.g., grating couplers) coupled to respective pixels or groups of pixels. Depending on the particular application, multiple illumination positions may be independently controllable using techniques described herein.

It should be appreciated that a fluorescence detection system may include multiple processors. For example, a first processor may be configured to measure signals from an integrated photodetector indicating detected fluorescence light and a second processor may be configured to obtain measurements of current output from pixels of an integrated photodetector for determining an illumination position. In this example, a third processor may be configured to control the illumination position, such as by controlling a relative positioning of the excitation light source and the integrated photodetector. Still in this example, a fourth processor may be configured to control the relative timing of control signals (e.g., B0 and B1) and/or the timing of the control signals with respect to excitation light pulses for controlling the timing of fluorescence detection. It should also be appreciated that any number of processors may be used to perform any or each of these operations (e.g., such as each being performed by the same processor), and that not all operations described herein need be performed depending on the application.

### V. Other Aspects and Examples

The following list of examples lists several possible non-limiting combinations of techniques described herein, which combinations may be combined into various sub-combinations depending on the particular application.

1. A method comprising measuring an amount of current output from a drain region of a pixel of an integrated photodetector.

2. The method of example 1, wherein the current output from the drain region is drawn along a bias path by applying a bias voltage to the drain region via the bias path.

3. The method of example 2, wherein applying the bias voltage to the drain region via the bias path comprises biasing the drain region to draw charge carriers from a photodetection region of the pixel.

4. The method of any one of examples 1 to 3, further comprising: generating, in the pixel, first charge carriers and second charge carriers in response to incident light received at the pixel; and transferring the first charge carriers to the drain region of the pixel and collecting the second charge carriers in a charge storage region of the pixel, wherein the amount of current output from the drain region corresponds to an amount of first charge carriers transferred to the drain region.

5. The method of example 4, further comprising: supporting a sample while the sample is illuminated with excitation light; generating the first charge carriers in response to the excitation light reaching the pixel; and generating the second charge carriers in response to fluorescent light from the sample reaching the pixel.

6. The method of any one of examples 1 to 5, wherein measuring comprises converting the amount of current to a voltage and digitizing the voltage to generate a digital signal indicative of the amount of current.

7. The method of any one of examples 1 to 6, further comprising: measuring a first amount of current output from at least one first drain region of at least one first pixel of the integrated photodetector, the at least one first pixel comprising the pixel, and the first amount of current comprising the amount of current; and measuring a second amount of current output from at least one second drain region of at least one second pixel of the integrated photodetector.

8. The method of example 7, wherein: the first amount of current is generated in the at least one first pixel in response to light received at the at least one first pixel from a first portion of an optical component of the integrated photodetector; the second amount of current is generated in the at least one second pixel in response to light received at the at least one second pixel from a second portion of the optical component; the first portion of the optical component and the second portion of the optical component receive the light along a first direction; and the first portion of the optical component is offset from the second portion of the optical component in a second direction substantially perpendicular to the first direction.

9. The method of example 8, wherein: the at least one first pixel comprises a first plurality of pixels; the at least one first drain region comprises a first plurality of drain regions that output the first amount of current in response to light received at the first plurality of pixels from the first portion of the optical component; the at least one second pixel comprises a second plurality of pixels; and the at least one second drain region comprises a second plurality of drain regions that generate the second amount of current in response to light received at the second plurality of pixels from the second portion of the optical component.

10. The method of any one of examples 7 to 9, wherein: measuring the first amount of current output from the at least one first drain region of the at least one first pixel comprises digitizing the first amount of current to generate a first digital signal indicating the first amount of current output from the at least one first drain region of the at least one first pixel; and measuring the second amount of current output from the at least one second drain region of the at least one second pixel comprises digitizing the second amount of current to generate a second digital signal indicating the second amount of current output from the at least one second drain region of the at least one second pixel.

11. The method of any one of examples 8 to 9, further comprising: measuring a third amount of current output from a third plurality of drain regions of a third plurality of pixels of the integrated photodetector, the third amount of current being output from the third plurality of drain regions of the third plurality of pixels in response to light received at the third plurality of pixels from a third portion of the optical component, wherein the third portion of the optical component is offset from the first portion and/or the second portion of the optical component in a third direction that is substantially perpendicular to each of the first and second directions.

12. The method of any one of examples 8 to 9 and 11, wherein the optical component comprises a grating coupler.

13. The method of any one of examples 1 to 4 and 6 to 12, wherein the amount of current output from the drain region of the pixel comprises charge carriers generated in the pixel in response to excitation light from an excitation light source.

14. The method of example 13, further comprising: illuminating a first position on the integrated photodetector with the excitation light; and illuminating a second position on the integrated photodetector with the excitation light, wherein the second position is offset from the first position in the second direction.

15. The method of example 14 further comprising sweeping the excitation light over a plurality of positions, including the first and second positions, on the integrated photodetector, wherein the plurality of positions on the integrated photodetector are offset from one another in the second direction.

16. The method of any one of examples 14 to 15, further comprising: illuminating a third position on the integrated photodetector with the excitation light, wherein the third position is offset from the first and second positions in the third direction.

17. An integrated photodetector comprising a pixel and configured to perform the method of any one of examples 1 to 13.

18. A system comprising an integrated photodetector and an excitation light source configured to perform the method of any one of examples 14 to 16.

19. A method comprising determining an illumination position on an integrated photodetector based, at least in part, on a measurement of current output from a drain region of a pixel of the integrated photodetector.

20. The method of example 19, wherein the measurement of current output from the drain region of the pixel of the integrated photodetector corresponds to an amount of first charge carriers transferred to the drain region of the pixel.

21. The method of example 19 or 20, wherein the measurement of current comprises a digital signal comprising a digitized voltage converted from an amount of current output from the drain region of the pixel.

22. The method of any one of examples 19 to 21, wherein: the illumination position on the integrated photodetector is determined for illuminating the integrated photodetector with excitation light substantially in a first direction; and the illumination position on the integrated photodetector is determined from among a plurality of illumination positions on the integrated photodetector that are offset from one another in a second direction substantially perpendicular to the first direction.

23. The method of example 22, further comprising substantially aligning an excitation light source with an optical component of the integrated photodetector in the second direction at least in a part by moving the excitation light source and/or the integrated photodetector to illuminate, using the excitation light source, another illumination position on the integrated photodetector that is offset from the illumination position in the second direction.

24. The method of example 22, wherein the illumination position on the integrated photodetector is further determined from among a second plurality of illumination positions on the integrated photodetector that are offset from one another in a third direction substantially perpendicular to each of the first and second directions.

25. The method of example 24, further comprising substantially aligning an excitation light source with an optical component of the integrated photodetector in the second and third directions at least in a part by moving the excitation light source and/or the integrated photodetector to illuminate, using the excitation light source, another illumination position on the integrated photodetector that is offset from the illumination position in the third direction.

26. The method of example 19 to 21, wherein the measurement of current output from the drain region of the pixel comprises: a first signal indicating a first amount of current output from at least one first drain region of at least one first pixel, the at least one first pixel comprising the pixel and the at least one first drain region comprising the drain region; and a second signal indicating a second amount of current output from at least one second pixel of the integrated photodetector.

27. The method of example 26, wherein determining the illumination position on the integrated photodetector comprises combining the first and second signals.

28. The method of example 27, wherein the illumination positioned is determined to be a point of substantially equal amounts of current indicated in the first and second signals.

29. The method of example 28, wherein combining the first and second signals comprises subtracting the second signal from the first signal to determine the point of substantially equal amounts of current indicated in the first and second signals.

30. The method of example 28 or 29, wherein determining the illumination position further comprises normalizing the first and second signals based on substantial maximum amounts of current for the at least one first pixel and the at least one second pixel, respectively.

31. The method of any one of examples 26 to 30, wherein: the first signal is obtained from the at least one first pixel in response to the at least one first pixel receiving light from a first portion of an optical component of the integrated photodetector, the first portion of the optical component receiving the light in a first direction; the second signal is obtained from the at least one second pixel in response to the at least one second pixel receiving light from a second portion of the optical component, the second portion of the optical component receiving the light in the first direction; and the first portion of the optical component is offset from the second portion of the optical component in a second direction substantially perpendicular to the first direction.

32. The method of example 31, wherein: the first signal is obtained from a first plurality of pixels of the at least one first pixel that receive the light from the first portion of the optical component; and the second signal is obtained from a second plurality of pixels of the at least one second pixel that receive the light from the second portion of the optical component.

33. The method of example 32, wherein the measurement of current output from the drain region of the pixel further comprises: a third signal indicating a third amount of current output from a third plurality of drain regions of a third plurality of pixels that receive the light from a third portion of the optical component offset from the first and second portions of the optical component in a third direction substantially perpendicular to each of the first and second directions.

34. The method of example 33, wherein determining the illumination position on the integrated photodetector comprises combining the first, second, and third signals.

35. The method of example 34, wherein the illumination positioned is determined to be a point of substantially equal amounts of current indicated in the first, second, and third signals.

36. The method of example 34 or 35, wherein determining the illumination position on the integrated photodetector comprises normalizing the first, second, and third signals based on substantial maximum amounts of current for the first plurality of pixels, the second plurality of pixels, and the third plurality of pixels, respectively.

37. The method of any one of examples 31 to 36, further comprising: illuminating a first position on the integrated photodetector with excitation light from an excitation light source; and illuminating a second position on the integrated photodetector with the excitation light, wherein the second position is offset from the first position in the second direction.

38. The method of example 37 further comprising sweeping the excitation light from the excitation light source over a plurality of positions, including the first and second positions, on the integrated photodetector, wherein the plurality of positions on the integrated photodetector are offset from one another in the second direction.

39. The method of example 37 or 38, further comprising: illuminating a third position on the integrated photodetector with the excitation light from the excitation light source, wherein the third position is offset from the first and second positions in the third direction.

40. A system comprising a processor configured to perform the method of any one of examples 19 to 36.

41. A non-transitory computer-readable medium having instructions encoded thereon that, when executed by a processor, cause the processor to perform the method of any one of examples 19 to 36.

42. A system comprising a processor and an excitation light source, the system configured to perform the method of any one of examples 37 to 39.

43. A method comprising measuring an amount of current output from a pixel of an integrated photodetector, the amount of current corresponding to an amount of excitation light received at the pixel.

44. The method of example 43, further comprising: generating, in the pixel, first charge carriers and second charge carriers in response to incident light received at the pixel, the incident light comprising the excitation light and the first charge carriers corresponding to the excitation light; and transferring the first charge carriers to a drain region of the pixel and collecting the second charge carriers in a charge storage region of the pixel, wherein the amount of current output from the drain region corresponds to an amount of first charge carriers transferred to the drain region.

45. The method of example 44, further comprising: supporting a sample while the sample is illuminated with the excitation light; generating the first charge carriers in response to the excitation light reaching the pixel; and generating the second charge carriers in response to fluorescent light from the sample reaching the pixel.

46. The method of any one of examples 43 to 45, wherein measuring comprises converting the amount of current to a voltage and digitizing the voltage to generate a digital signal indicative of the amount of current.

47. The method of any one of examples 43 to 46, further comprising: measuring a first amount of current output from at least one first pixel of the integrated photodetector, the first amount of current corresponding to a first amount of the excitation light received at the at least one first pixel; and measuring a second amount of current output from at least one second pixel of the integrated photodetector, the second amount of current corresponding to a second amount of the excitation light received at the at least one second pixel, wherein the at least one first pixel comprises the pixel and the first amount of current comprises the amount of current.

48. The method of example 47, wherein: the first amount of current is generated in the at least one first pixel in response to the first amount of the excitation light being received at the at least one first pixel from a first portion of an optical component of the integrated photodetector; the second amount of current is generated in the at least one second pixel in response to the second amount of the excitation light being received at the at least one second pixel from a second portion of the optical component; the first portion of the optical component and the second portion of the optical component receive the light along a first direction; and the first portion of the optical component is offset from the second portion of the optical component in a second direction substantially perpendicular to the first direction.

49. The method of example 48, wherein: the at least one first pixel comprises a first plurality of pixels that output the first amount of current in response to light received at the first plurality of pixels from the first portion of the optical component; the at least one second pixel comprises a second plurality of pixels that generate the second amount of current in response to light received at the second plurality of pixels from the second portion of the optical component.

50. The method of any one of examples 47 to 49, wherein: measuring the first amount of current output from the at least one first pixel comprises digitizing the first amount of current to generate a first digital signal indicating the first amount of current output from the at least one first pixel; and measuring the second amount of current output from the at least one second pixel comprises digitizing the second amount of current to generate a second digital signal indicating the second amount of current output from the at least one second pixel.

51. The method of any one of examples 48 to 49, further comprising: measuring a third amount of current output from a third plurality of pixels of the integrated photodetector, the third amount of current being output from the third plurality of pixels in response to light received at the third plurality of pixels from a third portion of the optical component, wherein the third portion of the optical component is offset from the first portion and/or the second portion of the optical component in a third direction that is substantially perpendicular to each of the first and second directions.

52. The method of any one of examples 48 to 49 and 51, wherein the optical component comprises a grating coupler.

53. The method of any one of examples 43 to 44 and 46 to 52, further comprising: illuminating a first position on the integrated photodetector with the excitation light; and illuminating a second position on the integrated photodetector with the excitation light, wherein the second position is offset from the first position in the second direction.

54. The method of example 53, further comprising sweeping the excitation light over a plurality of positions, including the first and second positions, on the integrated photodetector, wherein the plurality of positions on the integrated photodetector are offset from one another in the second direction.

55. The method of any one of examples 53 to 54, further comprising: illuminating a third position on the integrated photodetector with the excitation light, wherein the third position is offset from the first and second positions in the third direction.

56. An integrated photodetector comprising a pixel and configured to perform the method of any one of examples 43 to 52.

57. A system comprising an integrated photodetector and an excitation light source configured to perform the method of any one of examples 53 to 55.

Having thus described several aspects and embodiments of the technology of the present disclosure, it is to be appreciated that various alterations, modifications, and improvements will readily occur to those of ordinary skill in the art. Such alterations, modifications, and improvements are intended to be within the spirit and scope of the technology described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The above-described embodiments may be implemented in any of numerous ways. One or more aspects and embodiments of the present disclosure involving the performance of processes or methods may utilize program instructions executable by a device (e.g., a computer, a processor, or other device) to perform, or control performance of, the processes or methods. In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above. The computer readable medium or media may be transportable, such that the program or programs stored thereon may be loaded onto one or more different computers or other processors to implement various ones of the aspects described above. In some embodiments, computer readable media may be non-transitory media.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present disclosure need not reside on a single computer or processor, but may be distributed in a modular fashion among a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a Personal Digital Assistant (PDA), a smartphone or any other suitable portable or fixed electronic device.

Also, a computer may have one or more input and output devices. These devices may be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “substantially,” “approximately,” and “about” may be used to mean within ±20% of a target value in some embodiments, within ±10% of a target value in some embodiments, within ±5% of a target value in some embodiments, and yet within ±2% of a target value in some embodiments. The terms “substantially,” “approximately,” and “about” may include the target value.

1. A method comprising:
determining an illumination position on an integrated photodetector based, at least in part, on a measurement of an amount of current output from a pixel of the integrated photodetector,
wherein the amount of current corresponds to an amount of excitation light received at the pixel.

2. The method of claim 1, wherein the measurement is obtained, at least in part, by applying, via a bias path, a bias voltage to a drain region of the pixel to draw the current output from a photodetection region of the pixel.

3. The method of claim 1, wherein:
the illumination position on the integrated photodetector is determined for illuminating the integrated photodetector with excitation light substantially in a first direction; and
the illumination position on the integrated photodetector is determined from among a plurality of illumination positions on the integrated photodetector that are offset from one another in a second direction substantially perpendicular to the first direction.

4. The method of claim 3, wherein:
the pixel is a first pixel and the measurement is a first measurement;
determining the illumination position is further based on a difference between the first measurement and a second measurement of an amount of current output from a second pixel of the integrated photodetector, the amount of current corresponding to an amount of the excitation light received at the second pixel.

5. The method of claim 4, wherein:
the first amount of current is generated in the first pixel in response to the excitation light received at the first pixel from a first portion of an optical component of the integrated photodetector;
the second amount of current is generated in the second pixel in response to the excitation light received at the second pixel from a second portion of the optical component;
the first portion and the second portion of the optical component receive the excitation light substantially in the first direction; and
the first portion of the optical component is offset from the second portion of the optical component in the second direction.

6. The method of claim 5, wherein:
the first measurement corresponds to an amount of current output from a first plurality of pixels that comprises the first pixel, the amount of current corresponding to an amount of the excitation light received at the first plurality of pixels, and the first amount of current being generated in the first plurality of pixels in response to the excitation light received at the first plurality of pixels from the first portion of the optical component; and
the second measurement corresponds to an amount of current output from a second plurality of pixels that comprises the second pixel, the amount of current corresponding to an amount of the excitation light received at the second plurality of pixels, and the second amount of current being generated in the second plurality of pixels in response to the excitation light received at the second plurality of pixels from the second portion of the optical component.

7. The method of claim 1, wherein:
the pixel comprises:
a photodetection region configured to receive the excitation light and fluorescent light emitted by a sample in response to the sample being excited by the excitation light;
a charge storage region configured to receive first charge carriers from the photodetection region, the first charge carriers generated in response to receiving the fluorescent light; and
a drain region configured to receive second charge carriers from the photodetection region, the second charge carriers generated in response to receiving the excitation light; and
the amount of current output further corresponds to a number of the second charge carriers received in the drain region of the pixel.

8. A system comprising a processor configured to:
determine an illumination position on an integrated photodetector based, at least in part, on a measurement of an amount of current output from a pixel of the integrated photodetector,
wherein the amount of current corresponds to an amount of excitation light received at the pixel.

9. The system of claim 8, wherein:
the processor is configured to determine the illumination position on the integrated photodetector for illuminating the integrated photodetector with excitation light substantially in a first direction, and
the processor is configured to determine the illumination position on the integrated photodetector from among a plurality of illumination positions on the integrated photodetector that are offset from one another in a second direction substantially perpendicular to the first direction.

10. The system of claim 9, wherein:
the pixel is a first pixel and the measurement is a first measurement; and
the processor is configured to determine the illumination position further based on a difference between the first measurement and a second measurement of an amount of current output from a second pixel of the integrated photodetector, the amount of current corresponding to an amount of the excitation light received at the second pixel.

11. The system of claim 10, further comprising:
the integrated photodetector, wherein:
the integrated photodetector comprises an optical component configured to receive the excitation light substantially in the first direction and the optical component comprises a first portion and a second portion that is offset from the first portion in the second direction;
the first pixel is configured to generate the first amount of current in response to the excitation light received at the first pixel from the first portion of the optical component;
the second pixel is configured to generate the second amount of current in response to the excitation light received at the second pixel from the second portion of the optical component.

12. The system of claim 11, wherein the integrated photodetector comprises:
a first plurality of pixels that comprises the first pixel, the first measurement corresponding to an amount of current output from the first plurality of pixels, the amount of current corresponding to an amount of the excitation light received at the first plurality of pixels, and the first plurality of pixels configured to generate the first amount of current in response to the excitation light received at the first plurality of pixels from the first portion of the optical component; and
a second plurality of pixels that comprises the second pixel, the second measurement corresponding to an amount of current output from the second plurality of pixels, the amount of current corresponding to an amount of the excitation light received at the second plurality of pixels, and the second plurality of pixels configured to generate the second amount of current in response to the excitation light received at the second plurality of pixels from the second portion of the optical component.

13. The system of claim 8, further comprising:
the integrated circuit, wherein:
the pixel comprises:
a photodetection region configured to receive the excitation light and fluorescent light emitted by a sample in response to the sample being excited by the excitation light;
a charge storage region configured to receive first charge carriers from the photodetection region, the first charge carriers generated in response to receiving the fluorescent light; and
a drain region configured to receive second charge carriers from the photodetection region, the second charge carriers generated in response to receiving the excitation light; and
the amount of current output further corresponds to a number of the second charge carriers received in the drain region of the pixel.

14. An integrated photodetector comprising:
a pixel configured to receive excitation light,
wherein the integrated photodetector is configured to provide a measurement of an amount of current output from the pixel, and the amount of current output corresponds to an amount of the excitation light received at the pixel.

15. The integrated photodetector of claim 14, wherein:
the pixel comprises a photodetection region; and
the integrated photodetector is configured to obtain the measurement, at least in part, by applying, via a bias path, a bias voltage to a drain region of the pixel to draw the current output from the photodetection region.

16. The integrated photodetector of claim 14, further comprising:
a second pixel, wherein the pixel is a first pixel and the measurement is a first measurement,
wherein the integrated photodetector is configured to provide a second measurement of an amount of current output from the second pixel, and the amount of current output corresponds to an amount of the excitation light received at the second pixel.

17. The integrated photodetector of claim 16, further comprising:
an optical component configured to receive the excitation light along a first direction and having a first portion and a second portion that is offset from the first portion in a second direction substantially perpendicular to the first direction,
wherein:
the first pixel is configured to generate the first amount of current in response to the excitation light received at the first pixel from the first portion of the optical component; and
the second pixel is configured to generate the second amount of current in response to the excitation light received at the second pixel from the second portion of the optical component.

18. The integrated photodetector of claim 17, further comprising:
a first plurality of pixels that comprises the first pixel, the first measurement corresponding to an amount of current output from the first plurality of pixels, the amount of current corresponding to an amount of the excitation light received at the first plurality of pixels, and the first plurality of pixels configured to generate the first amount of current in response to the excitation light received at the first plurality of pixels from the first portion of the optical component; and
a second plurality of pixels that comprises the second pixel, the second measurement corresponding to an amount of current output from the second plurality of pixels, the amount of current corresponding to an amount of the excitation light received at the second plurality of pixels, and the second plurality of pixels configured to generate the second amount of current in response to the excitation light received at the second plurality of pixels from the second portion of the optical component.

19. The integrated photodetector of claim 14, wherein the pixel comprises a reaction chamber configured to support the sample and a photodetection region positioned to receive fluorescent light emitted by the sample in response to the sample being excited by the excitation light.

20. The integrated photodetector of claim 19, wherein the pixel further comprises:
a charge storage region configured to receive first charge carriers from the photodetection region, the photodetection region being configured to generate the first charge carriers in response to receiving the fluorescent light; and
a drain region configured to receive second charge carriers from the photodetection region, the photodetection region being configured to generate the second charge carriers in response to receiving the excitation light,
and wherein the amount of current output further corresponds to a number of the second charge carriers received in the drain region.
